(19) United States
(12) Patent Application Publication
(10) Pub. No.: US 2012/0184082 A1
(43) Pub. Date: Jul. 19, 2012

(54) MANUFACTURING METHOD OF SEMICONDUCTOR DEVICE

(75) Inventors: Keiichi AIZAWA, Kanagawa (JP); Shinya HOSAKA, Kanagawa (JP)

(73) Assignee: RENESAS ELECTRONICS CORPORATION, Kanagawa (JP)

(21) Appl. No.: 13/347,742

(22) Filed: Jan. 11, 2012

(30) Foreign Application Priority Data
Jan. 17, 2011 (JP) 2011-006781

(51) Int. Cl. H01L 21/762

(52) U.S. Cl. 438/430; 257/E21.545

(57) ABSTRACT

A high power amplifier used for a front end module of a cellular telephone is a silicon-based CMOS integrated circuit. The output stage of the amplifier includes an LDMOSFET portion in which many LDMOSFET cells are integrated. In the LDMOSFET cell, to reduce the resistance between a backside source electrode and a surface source region, a polysilicon plug doped with boron in a high concentration is embedded into a semiconductor substrate. The polysilicon plug contracts due to solid phase epitaxial growth caused by a heat treatment to generate strain in the silicon substrate. The manufacturing method of a semiconductor device such as an LDMOSFET includes forming a hole passing through an epitaxial layer from the surface of a substrate and embedding a polysilicon plug. A polysilicon member is deposited out in a state where a thin silicon oxide film exists on the inner surface of the hole.

### CROSS-REFERENCE TO RELATED APPLICATION

The disclosure of Japanese Patent Application No. 2011-6781 filed on Jan. 17, 2011 including the specification, drawings and abstract is incorporated herein by reference in its entirety.

### BACKGROUND

The present invention relates to a technique useful when applied to a technique of embedding a polysilicon plug into a semiconductor substrate in a manufacturing method of semiconductor devices (or semiconductor integrated circuit devices).

Japanese Patent Laid-Open No. 2008-244382 (Patent Document 1), or US Patent Application No. 2008-237736 (Patent Document 2) corresponding to it discloses an example of providing a silicon plug doped with boron in a high concentration for an LDMOSFET (Laterally Diffused Metal Oxide Semiconductor Field Effect Transistor) portion of a semiconductor integrated circuit chip.

### SUMMARY

A chip for a high power amplifier (High-Power-AMP) used for a front end module or the like in a cellular telephone or the like is an analog and digital mixed device in accordance with a silicon-based CMOS integrated circuit. The output stage of the high power amplifier includes an LDMOSFET portion in which many LDMOSFET cells are integrated to constitute a plurality of LDMOSFETs. In the LDMOSFET cell, to reduce the resistance between a backside source electrode and a surface source region, a polysilicon plug doped with boron in a high concentration is embedded into a semiconductor substrate. The examination about the polysilicon plug by present inventors clarified that the polysilicon plug contracts due to solid phase epitaxial growth of the polysilicon plug caused by a heat treatment and then generated strain in the silicon substrate, causing leak defect.

The present invention was made for solving these problems.

The present invention provides a manufacturing step of a semiconductor device with a high reliability.

The description of the present specification and the accompanying drawings will clarify the other purposes and the new feature of the present invention.

The following briefly outlines atypical invention among the inventions disclosed in the present application.

An invention of the present application, in a manufacturing method of a semiconductor device such as an LDMOSFET, in forming a hole passing through an epitaxial layer from the surface of a substrate and embedding a silicon plug (polysilicon plug), deposits a polysilicon member in a state where a thin silicon oxide film is on the inner surface of the hole.

The following explains briefly the effect acquired by the typical invention among the inventions disclosed in the present application.

In a manufacturing method of a semiconductor device such as an LDMOSFET, when a hole passing through an epitaxial layer from the surface of a substrate is formed and a silicon plug (or a polysilicon plug) is embedded, a polysilicon member is deposited with a thin silicon oxide film on the inner surface of the hole. This can avoid strain caused by solid phase epitaxial growth of the polysilicon member due to a subsequent high-temperature heat treatment (800 degrees centigrade or more).

### BRIEF DESCRIPTION OF THE DRAWINGS

FIG. 1 is a top view of a chip for explaining a high-frequency high power amplifier, which is an objective device in the manufacturing method of a semiconductor device in accordance with an embodiment of the present application, and a device chip layout of the LDMOSFET portion;

FIG. 2 is an expanded plan view of a region R1 cut out from a limited part of the LDMOSFET portion in FIG. 1;

FIG. 3 is an expanded plan view corresponding to a region R2 cut out from a region near a half cell in FIG. 2 for explaining the device structure of the LDMOSFET portion in the high-frequency high power amplifier, which is the objective device in the manufacturing method of a semiconductor device in accordance with the embodiment of the application;

FIG. 4 is a cross-sectional view of the device corresponding to the cross section indicated by X-X′ in FIG. 3;

FIG. 5 is a flowchart of a pretreatment step of embedding polysilicon member, which is the essential part in the manufacturing method of a semiconductor device in accordance with the embodiment of the present application;

FIG. 6 is a cross-sectional view of a device on the way of a manufacturing step (a step of forming a hard mask film for trench etching) corresponding to FIG. 4 (the cross section indicated by X-X′ in FIG. 3) for outlining the step in the manufacturing method of a semiconductor device in accordance with the embodiment of the present application;

FIG. 7 is a cross-sectional view of the device on the way of a manufacturing step (a step of coating a resist film for trench etching) corresponding to FIG. 4 (the cross section indicated by X-X′ in FIG. 3) for outlining the step in the manufacturing method of a semiconductor device in accordance with the embodiment of the present application;

FIG. 8 is a cross-sectional view of the device on the way of a manufacturing step (a step of patterning a resist film for trench etching) corresponding to FIG. 4 (the cross section indicated by X-X′ in FIG. 3) for outlining the step in the manufacturing method of a semiconductor device in accordance with the embodiment of the present application;

FIG. 9 is a cross-sectional view of the device on the way of a manufacturing step (a step of patterning a hard mask film for trench etching) corresponding to FIG. 4 (the cross section indicated by X-X′ in FIG. 3) for outlining the step in the manufacturing method of a semiconductor device in accordance with the embodiment of the present application;

FIG. 10 is a cross-sectional view of the device on the way of a manufacturing step (a step of trench etching) corresponding to FIG. 4 (the cross section indicated by X-X′ in FIG. 3) for outlining the step in the manufacturing method of a semiconductor device in accordance with the embodiment of the present application;

FIG. 11 is a cross-sectional view of the device on the way of a manufacturing step (a step of removing a hard mask film for trench etching and a pretreatment step of embedding polysilicon member) corresponding to FIG. 4 (the cross section indicated by X-X′ in FIG. 3) for outlining the step in the manufacturing method of a semiconductor device in accordance with the embodiment of the present application;

FIG. 12 is a cross-sectional view of the device on the way of a manufacturing step (a step of embedding polysilicon member) corresponding to FIG. 4 (the cross section indicated by X-X′ in FIG. 3) for outlining the step in the manufacturing method of a semiconductor device in accordance with the embodiment of the present application;

FIG. 13 is a cross-sectional view of the device on the way of a manufacturing step (a step of planarizing a surface) corresponding to FIG. 4 (the cross section indicated by X-X′ in FIG. 3) for outlining the step in the manufacturing method of a semiconductor device in accordance with the embodiment of the present application;

FIG. 14 is a cross-sectional view of the device on the way of a manufacturing step (a step of forming STI) corresponding to FIG. 4 (the cross section indicated by Y-Y′ in FIG. 3) for outlining the step in the manufacturing method of a semiconductor device in accordance with the embodiment of the present application;

FIG. 15 is a cross-sectional view of the device on the way of a manufacturing step (a step of forming a diffusion structure and a gate one) corresponding to FIG. 4 (the cross section indicated by X-X′ in FIG. 3) for outlining the step in the manufacturing method of a semiconductor device in accordance with the embodiment of the present application;

FIG. 16 is a cross-sectional view of the device on the way of a manufacturing step (a step of forming a silicide layer) corresponding to FIG. 4 (the cross section indicated by X-X′ in FIG. 3) for outlining the step in the manufacturing method of a semiconductor device in accordance with the embodiment of the present application;

FIG. 17 is a cross-sectional view of the device on the way of a manufacturing step (a step of forming a premetal insulating film and a contact hole) corresponding to FIG. (the cross section indicated by X-X′ in FIG. 3) for outlining the step in the manufacturing method of a semiconductor device in accordance with the embodiment of the present application;

FIG. 18 is a cross-sectional view of the device on the way of a manufacturing step (a step of embedding a tungsten plug into a contact hole) corresponding to FIG. 4 (the cross section indicated by X-X′ in FIG. 3) for outlining the step in the manufacturing method of a semiconductor device in accordance with the embodiment of the present application;

FIG. 19 is a cross-sectional view of the device on the way of a manufacturing step (a step of forming metal first layer tungsten wiring) corresponding to FIG. 4 (the cross section indicated by X-X′ in FIG. 3) for outlining the step in the manufacturing method of a semiconductor device in accordance with the embodiment of the present application;

FIG. 20 is a cross-sectional view of the device on the way of a manufacturing step (a step of forming an inter-wiring-layer insulating film and embedding a tungsten plug into a through hole) corresponding to FIG. 4 (the X-X′ cross-section in FIG. 3) for outlining the step in the manufacturing method of a semiconductor device in accordance with the embodiment of the present application;

FIG. 21 is a cross-sectional view of the device on the way of a manufacturing step (a step of forming an aluminum-based wiring layer and final passivation) corresponding to FIG. 4 (the cross section indicated by X-X′ in FIG. 3) for outlining the step in the manufacturing method of a semiconductor device in accordance with the embodiment of the present application;

FIG. 22 is a cross-sectional view of the device on the way of a manufacturing step (a step of forming a backside metal electrode) corresponding to FIG. 4 (the cross section indicated by X-X′ in FIG. 3) for outlining the step in the manufacturing method of a semiconductor device in accordance with the embodiment of the present application;

FIG. 23 is an expanded plan view corresponding to the region R2 cut out from the region near the half cell in FIG. 2 for explaining a modified device structure corresponding to FIG. 3;

FIG. 24 is an expanded schematic cross-sectional view (for purposes of illustration, the horizontal width and thicknesses of a natural oxide film 34 and a thin silicon oxide film 35 are exaggerated, but they are original in FIGS. 25 and 26) of the region 3 cut out from the region near the polysilicon plug for explaining the detailed step (before a pretreatment step of embedding the polysilicon member or on completion of the first APM cleaning) of the step in FIG. 11;

FIG. 25 is an expanded schematic cross-sectional view of the region R3 cut out from the region near the polysilicon plug for explaining the detailed step (on completion of the DHF cleaning) of the step in FIG. 11;

FIG. 26 is an expanded schematic cross-sectional view of the region R3 cut out from the region near the polysilicon plug for explaining the detailed step (on completion of the second APM cleaning) of the step in FIG. 11;

FIG. 27 is a cross-sectional SEM (Scanning Electron Micrograph) which shows the region near the silicon plug of the semiconductor device in the manufacturing method of a semiconductor device in accordance with the embodiment of the present application; and

FIG. 28 is a cross-sectional SEM (Scanning Electron Micrograph) of the region near the silicon plug of a semiconductor device by a cleaning step in comparative example (a cleaning step without the second APM cleaning in FIG. 5).

### DETAILED DESCRIPTION

### [Outline of Embodiment]

First, representative embodiments of the invention disclosed in the present application are explained.

1. A manufacturing method of a semiconductor device including the steps of: (a) preparing a first conductivity type silicon-based single-crystal wafer having a first semiconductor layer of a first impurity concentration, and a second semiconductor layer of a second impurity concentration adjacent to the first semiconductor layer and having the same conductivity type as the first semiconductor layer; (b) forming a plug-embedding hole that passes through the second semiconductor layer from a first main surface of the wafer toward a second main surface on the first semiconductor layer to reach an inside of the first semiconductor layer; (c) after the step (b), depositing a polysilicon member on the first main surface of the wafer with a thin silicon oxide-based film on the inner surface of the hole to embed the inside of the hole with the polysilicon member; (d) removing the polysilicon member outside the hole to form a polysilicon plug; and (e) after the step (d), performing a heat treatment on the wafer at 800 degrees Celsius.

2. In the manufacturing method of a semiconductor device in accordance with Item 1, the polysilicon plug constitutes a current path between a surface source region; which is an LDMOSFET, or an LDMOSFET portion of the semiconductor device and is provided on the first main surface of the wafer; and a backside source electrode provided on the second main surface of the wafer.

3. In the manufacturing method of a semiconductor device in accordance with Item 1, the polysilicon plug constitutes a current path between a surface source region; which is an LDMOSFET portion of the semiconductor device and is provided on the first main surface of the wafer; and a backside source electrode provided on the second main surface of the wafer.

4. In the manufacturing method of a semiconductor device in accordance with any one of Items 1 to 3, the polysilicon plug is doped with boron.

5. In the manufacturing method of a semiconductor device according to any one of Items 1 to 4, the first semiconductor layer is a P-type silicon substrate of the wafer, and the second semiconductor layer is a P-type epitaxial silicon layer of the wafer.

6. In the manufacturing method of a semiconductor device in accordance with any one of Items 1 to 5, CVD deposits the polysilicon member.

7. In the manufacturing method of a semiconductor device in accordance with any one of Items 1 to 6, an oxidizing chemical solution forms the thin silicon oxide-based film.

8. In the manufacturing method of a semiconductor device in accordance with any one of Items 1 to 7, further including the step of (f) after the step (b) and before the step (c), performing a pretreatment for embedding polysilicon member and including the substeps of (f1) performing a cleaning process on the surface of the first main surface of the wafer including the inner surface of the plug-embedding hole by a first chemical solution that has a function of removing an oxide film; and (f2) after the substep (f1), performing a cleaning process on the surface of the first main surface of the wafer including the inner surface of the plug-embedding hole by a second chemical solution that has a function of forming an oxide film.

9. In the manufacturing method of a semiconductor device in accordance with Item 8, the second chemical solution is an aqueous solution including a hydrogen peroxide solution as one of main components.

10. In the manufacturing method of a semiconductor device in accordance with Item 8 or 9, the second chemical solution is an aqueous solution including ammonia as one of main components.

11. In the manufacturing method of a semiconductor device in accordance with any one of Items 8 to 10, the first chemical solution is an aqueous solution including hydrofluoric acid as one of main components.

12. In the manufacturing method of a semiconductor device in accordance with any one of Items 8 to 11, the step (f) further includes the substep of (f3) before the substep (f1) performing a cleaning process on the surface of the first main surface of the wafer including the inner surface of the plug-embedding hole by a third chemical solution that has a function of forming an oxide film.

13. In the manufacturing method of a semiconductor device in accordance with Item 12, the third chemical solution is an aqueous solution containing a hydrogen peroxide solution as one of main components.

14. In the manufacturing method of a semiconductor device in accordance with Item 12 or 13, the third chemical solution is an aqueous solution that includes ammonia as one of main components.

15. In the manufacturing method of a semiconductor device in accordance with any one of Items 1 to 14, the thickness of the thin silicon oxide-based film is from about 0.2 nm to about 2 nm at the start of the step (c).

16. In the manufacturing method of a semiconductor device in accordance with any one of Items 1 to 6 and 15, the thin silicon oxide-based film is a natural oxide film.

17. In the manufacturing method of a semiconductor device in accordance with Items 1 to 6 and 15, the thin silicon oxide-based film is a thermal oxide film.

18. In the manufacturing method of a semiconductor device in accordance with any one of Items 1 to 6 and 15, the thin silicon oxide-based film is an oxide film by CVD.

19. In the manufacturing method of a semiconductor device in accordance with any one of Items 1 to 6 and 15, the thin silicon oxide-based film is an oxide film by plasma oxidation.

20. In the manufacturing method of a semiconductor device in accordance with any one of Items 1 to 7 and 15 to 19, further including the step of (f) after the step (b) and before the step (c), performing a pretreatment for embedding polysilicon member and including the substeps of (f4) performing a first surface treatment that has a function of removing an oxide film on the surface of the first main surface of the wafer including an inner surface of the plug-embedding hole; and (f5) after the substep (f4), performing a second surface treatment that has a function of forming an oxide film on the surface of the first main surface of the wafer including the inner surface of the plug-embedding hole.

### [Explanation of Description Style, Fundamental Term and Usage in the Present Application]

1. In the present application, the embodiments will be described, being divided into plural sections, if necessary for convenience. Except for the case where it is clearly specified in particular, they are dependent on each other and are parts of an example. One is a detailed part or a modified example of a part or the whole of the other. The repetition of the same part is omitted, as a principle. In addition, constituents in the embodiments are dispensable, except for the case where it is clearly specified to the contrary in particular, where it is limited theoretically to the number, and where it is clearly not right from the context.

Furthermore, in the present application, a “semiconductor device” or a “semiconductor integrated circuit device” means, mainly, various transistors (active elements), and semiconductor chips with a resistance, a capacitor, and mainly a transistor integrated (a single-crystal silicon substrate). The various representative transistors include a MISFET (Metal Insulator Semiconductor Field Effect Transistor) represented by a MOSFET (Metal Oxide Semiconductor Field Effect Transistor). The representative integrated circuit includes a CMIS (Complementary Metal Insulator Semiconductor) type integrated circuit represented by a CMOS (Complementary Metal Oxide Semiconductor) type integrated circuit combining an N-channel type MISFET and a P-channel type MISFET.

In the present application, an “LDMOSFET” or a “MOSFET” is not limited to the case where a gate insulating film is an oxide.

The wafer step of semiconductor integrated circuit devices of the present day, that of LSI (Large Scale Integration), can be classified roughly, usually, into a FEOL (Front End of Line) step from the installation step of a silicon wafer as a raw material to a premetal step (a step including the formation of an interlayer insulating film between a lower edge of an Ml wiring layer and a gate electrode structure, the formation of a contact hole, the embedment of tungsten plug of the premetal part); and a BEOL (Back End of Line) step from the formation of the M1 wiring layer to the formation of a pad opening for a final passivation film over an aluminum-based pad electrode (in a wafer level package process, the process is also included).

2. Similarly, in the description of embodiments, when materials and components are referred to as “X made of A”, it does not exclude those having an element other than A as one of constituents, except for the case where it is clearly specified to the contrary in particular, and where it is clearly not right from the context. In a component, it means “X containing A as a main component”. A “silicon member” etc. are not limited to pure silicon, but include SiGe alloy and other multi-component alloys containing silicon as a main component, and members containing another impurity. Similarly, a “silicon oxide film,” a “silicon oxide-based insulating film” include not only comparatively pure undoped silicon dioxide, but also FSG (Fluorosilicate Glass), TEOS-based silicon oxide, SiOC (Silicon Oxicarbide) or carbon-doped silicon oxide, or thermal oxide films such as OSG (Organosilicate glass), PSG (Phosphorus Silicate Glass) and BPSG (Borophosphosilicate Glass), CVD oxide films, coating-based silicon oxide such as SOG (Spin ON Glass) and nano-clustering silica (NCS), silica-based low-k insulating films formed by introducing air into members similar to these (a porous-based insulating film), composite films with other silicon-based insulating films having these as a principal constituent.

As a silicon-based insulating film used regularly in semiconductor fields along with the silicon oxide-based insulating film, a silicon nitride-based insulating film is given. Materials belonging to this line include SiN, SiCN, SiNH, and SiCNH. “silicon nitride” includes both SiN and SiNH, except for the case where it is clearly specified to the contrary in particular. Similarly, “SiCN” means both SiCN and SiCNH, except for the case where it is clearly specified to the contrary in particular.

SiC as an insulating film has properties similar to those of SiN, but, in many cases, SiON is to be classified into a silicon oxide-based insulating film.

A silicon nitride film is used frequently as an etching stop film in a SAC (Self-Aligned Contact) technique, and, in addition, is also used as a stress-providing film in an SMT (Stress Memorization Technique).

Similarly, in the present application, as “silicide”, cobalt silicide was taken as an example and explained specifically, but silicide is not limited to cobalt silicide, but also to nickel silicide, titanium silicide, tungsten silicide. Moreover, with regard to nickel silicide, as a metal film for siliciding, in addition to a Ni (nickel) film, such nickel alloy film as a Ni—Pt alloy film (an alloy film of Ni and Pt), a Ni—V alloy film (an alloy film of Ni and V), a Ni—Pd alloy film (an alloy film of Ni and Pd), a Ni—Yb alloy film (an alloy film of Ni and Yb) or a Ni—Er alloy film (an alloy film of Ni and Er) may be used. These silicides containing nickel as a principal metal element are generically referred to as a “nickel-based silicide.”

3. Similarly, favorable examples are cited for figures, positions, attributes, but they are not limited strictly to the examples, except for the case where it is clearly specified to the contrary in particular, or it is not right clearly from the context.

4. Furthermore, in referring to a specified numeric value or numeric quantity, too, it may be a numeric value exceeding the specified value or numeric values less than the numeric value, except for the case where it is clearly specified to the contrary in particular, it is restricted theoretically to the specified number, and it is clearly not right from the context.

5. In referring to a “wafer”, usually it indicates a single crystalline silicon wafer over which a semiconductor device (a semiconductor integrated circuit device and an electronic device have the same meaning) is formed, but, it also includes composite wafers of an insulating substrate such as an epitaxial wafer, an SOI substrate or an LCD glass substrate with a semiconductor layer.

In referring to a “silicon-based single crystal wafer” or a “wafer of a silicon-based single crystal” in the present application, it shall include not only a wafer as cut out from a single crystalline body formed by a CZ method or a FZ method, but also an epitaxial wafer with an epitaxially grown silicon-based semiconductor member layer for one face thereof.

In referring to “polysilicon” in the present application, it shall include not only polycrystalline silicon, but also microcrystalline silicon and amorphous silicon. This is because the interconversion between these is difficult to be defined with a single meaning.

6. In referring to a “hole” or a “pore” in the present application, it shall include a circle, an approximate circle, a regular square, an ordinary rectangle, a long and narrow groove such as a trench (including winding one).

7. In referring to a “thin silicon oxide-based film,” a “silicon oxide-based thin film,” a “thin oxide film” or an “oxide thin film” in the application with regard to a pretreatment of the polysilicon plug, it means those having a thickness of around 0.5 nm (as a range, from about 0.2 nm to about 2 nm). The thickness of a natural oxide film is also thought to be approximately at this level.

### DETAILS OF EMBODIMENT

Embodiments are described in more detail. In drawings, the same or similar parts are shown by the same or similar symbols or reference numerals, and the explanation is not repeated as a principle.

In attached drawings, in the case where it becomes rather complicated or it is clearly distinguished from a void, hatching may be omitted even for a cross-section. In this context, when it is clear from the explanation, even for a closed pore in a plane, a profile line in the background may be omitted. Furthermore, to express clearly to be not a void, hatching may be attached when it is not a cross-section.

As a precedent patent application disclosing the silicon plug of an LDMOSFET, Japanese Patent Application No. 2009-153254 (filed on Jun. 29, 2009 in Japan) is cited.

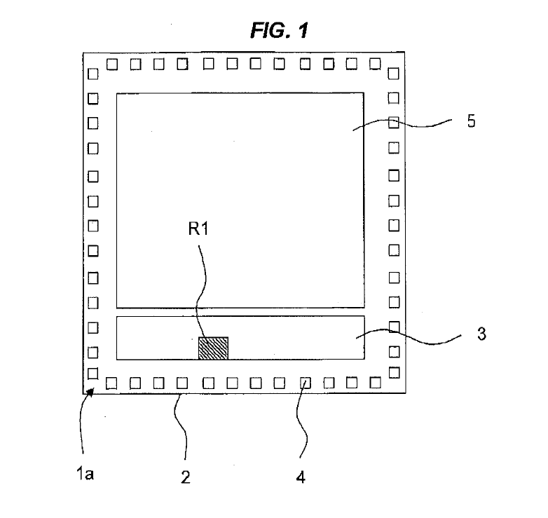

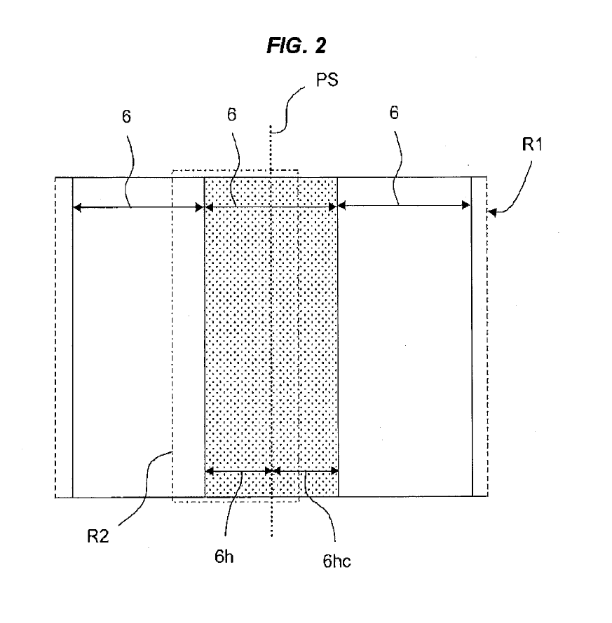

1. Explanation of a high-frequency high power amplifier being an objective device in the manufacturing method of a semiconductor device of an embodiment of the present application, and of a device chip layout of an LDMOSFET portion. (mainly FIGS. 1 and 2) As a unit cell structure of the LDMOSFET portion, one constituted from a half cell and a conjugated half cell that is of plane symmetry with regard to a plane of symmetry is explained specifically, but the present invention is not limited to it, and, one corresponding to the half cell may be the unit cell.

FIG. 1 is a top view of a chip for explaining a high-frequency high power amplifier, which is an objective device in the manufacturing method of a semiconductor device in accordance with an embodiment of the present application, and a device chip layout of the LDMOSFET portion. FIG. 2 is an expanded plan view of a region R1 cut out from a limited part of the LDMOSFET portion in FIG. 1. In accordance with these, a high-frequency high power amplifier, which is an objective device in the manufacturing method of a semiconductor device of an embodiment of the present application, and a device chip layout of the LDMOSFET portion are explained.

First, a chip upper face layout is explained based on FIG. 1. As shown in FIG. 1, many bonding pads 4 are provided in the surrounding part of a surface 1a of a semiconductor chip 2. A CMOS analog and digital mixed circuit portion 5 and an LDMOSFET portion 3 are provided in the internal region.

Next, FIG. 2 shows an expanded plan view of a region R1 cut out from a limited part of the LDMOSFET portion in FIG. 1 (in the LDMOSFET portion 3, usually, plural LDMOSFETs are formed. Since each of the LDMOSFETs is constituted of many unit cells, the unit cell and the surroundings are cut out and explained). As shown in FIG. 2, in each of the LDMOSFETs, plural unit cells 6 stand repeatedly in a line having a definite translational symmetry. In the example, each of the unit cells 6 is constituted from a half cell 6h and a conjugated half cell 6hc that are in plane symmetry mutually with respect to, for example, a symmetry plane PS (or a symmetry axis corresponding to the symmetry plane).

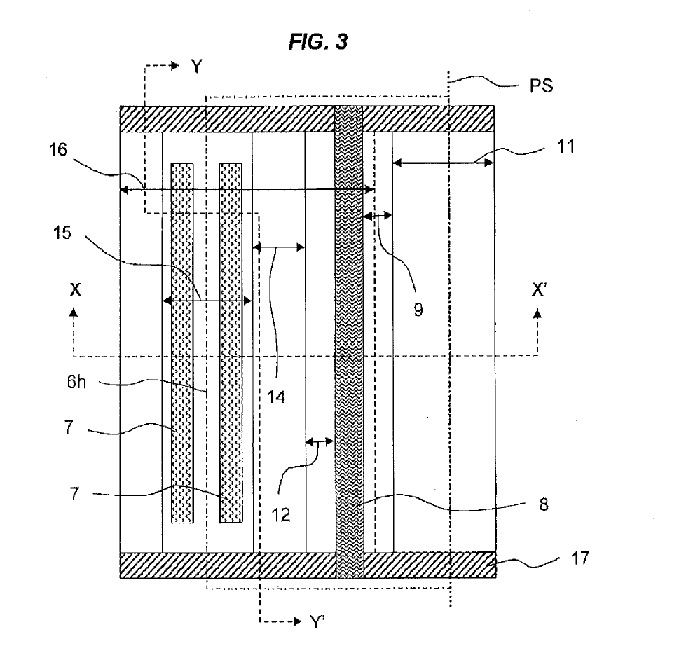

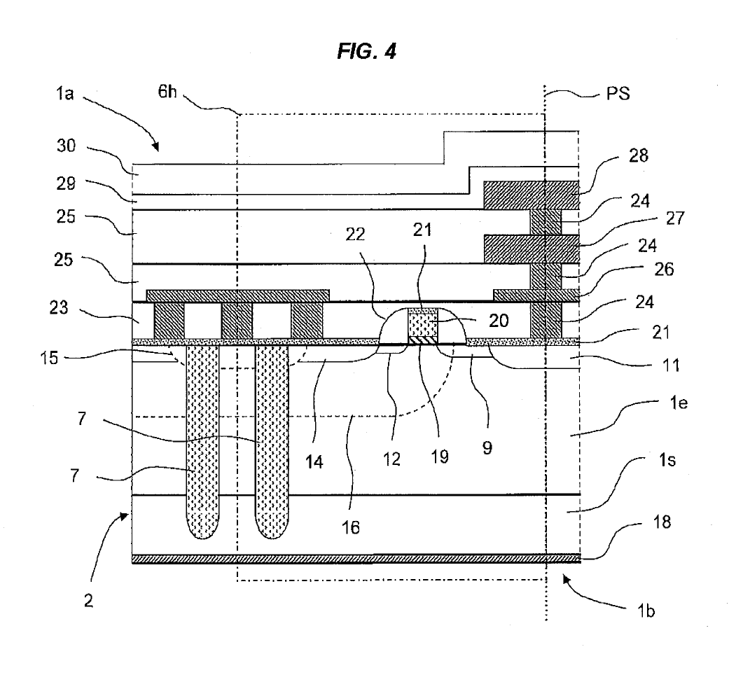

2. Explanation of a device structure of the LDMOSFET portion in the high-frequency high power amplifier, which is an objective device in the manufacturing method of a semiconductor device of an embodiment of the present application (mainly FIGS. 3 and 4). In this section, to explain the details of the half cell 6h in FIG. 2, the region R2 cut out from a region near a half cell in FIG. 2 is explained. As an example, one having source-drain breakdown voltage of around 10 V is explained specifically. A boron-doped polysilicon plug 7 (FIGS. 3 and 4) to be explained forms a current path between the surface source region and the backside source electrode, reduces source resistance by a relatively low resistance to keep high frequency properties, and is an important constituent as an LDMOSFET.

FIG. 3 is an expanded plan view corresponding to a region R2 cut out from a region near a half cell in FIG. 2 for explaining the device structure of the LDMOSFET portion in the high-frequency high power amplifier, which is the objective device in the manufacturing method of a semiconductor device in accordance with the embodiment of the application. FIG. 4 is a cross-sectional view of the device corresponding to the cross section indicated by X-X′ in FIG. 3;

As shown in FIGS. 3 and 4, a backside metal source electrode 18 is provided on the backside lb of the semiconductor chip 2 (on that of a semiconductor substrate part 1s (P+ single crystalline silicon substrate part)). A P-silicon epitaxial layer 1e (an epitaxial layer (a second semiconductor layer having a second impurity concentration)) having a thickness of around 2 micrometers is formed on the surface of the P+ single crystalline silicon substrate part is (a first semiconductor layer of a first conductivity type with a first impurity concentration). A P-type body region 16, an N+ type surface source region 14, an N-type surface source extension region 12, an N+-type drain region 11, an N-type drain extension region 9, a P₊- type surface source contact region 15 are provided in the surface region of the P-silicon epitaxial layer 1e. The boron-doped polysilicon plug 7 with a thickness of around 0.4 micrometers and a depth of around 2.7 micrometers is provided in the surface of the P-silicon epitaxial layer 1e, passes through the region, and reaches the P+ single crystalline silicon substrate part 1s. A polysilicon gate electrode 20 with a width of around 0.2 micrometers is provided over the surface of the P-silicon epitaxial layer 1e via a gate insulating film 19 (they are collectively called the “gate structure”). A sidewall 22 is provided around the polysilicon gate electrode 20. A silicide film, such as a cobalt silicide film 21, is formed over the surface of the P-silicon epitaxial layer 1e (over a source/drain region) and over a polysilicon gate electrode 20. A premetal insulating film 23 with a thickness of around 0.7 micrometers is provided over the surface of the gate structure and the P-silicon epitaxial layer 1e to cover the cobalt silicide film 21. A tungsten plug 24 is embedded into the premetal insulating film 23. Furthermore, a tungsten-based first layer wiring 26 is provided over the premetal insulating film 23. A multilayer aluminum-based wiring structure is provided over the tungsten-based first layer wiring 26 and includes an interlayer insulating film 25, the tungsten plug 24, an aluminum-based second layer wiring 27, and an aluminum-based third layer wiring 28. A final passivation structure is provided over the multilayer aluminum-based wiring structure and includes a silicon oxide-based final passivation film 29 and a silicon nitride-based final passivation film 30.

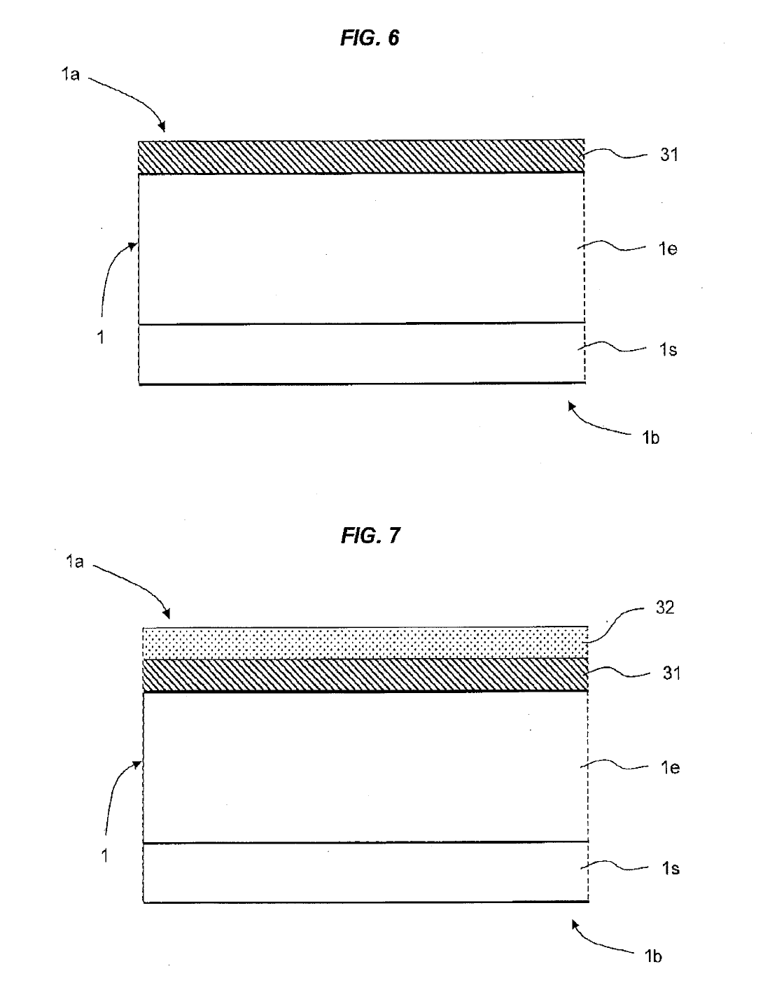

3. Explanation of an outline of a manufacturing step regarding the LDMOSFET portion in the high-frequency high power amplifier, which is an objective device in the manufacturing method of a semiconductor device of an embodiment of the present application (mainly FIGS. 6 to 22). In this section, an example of forming the device structure over a P-type single crystalline silicon wafer (or an epitaxial wafer having a P-silicon epitaxial layer on the epitaxial wafer) explained in sections 1 and 2 is explained specifically, but, if necessary, it may be formed over a wafer of another conductivity type or another structure or material.

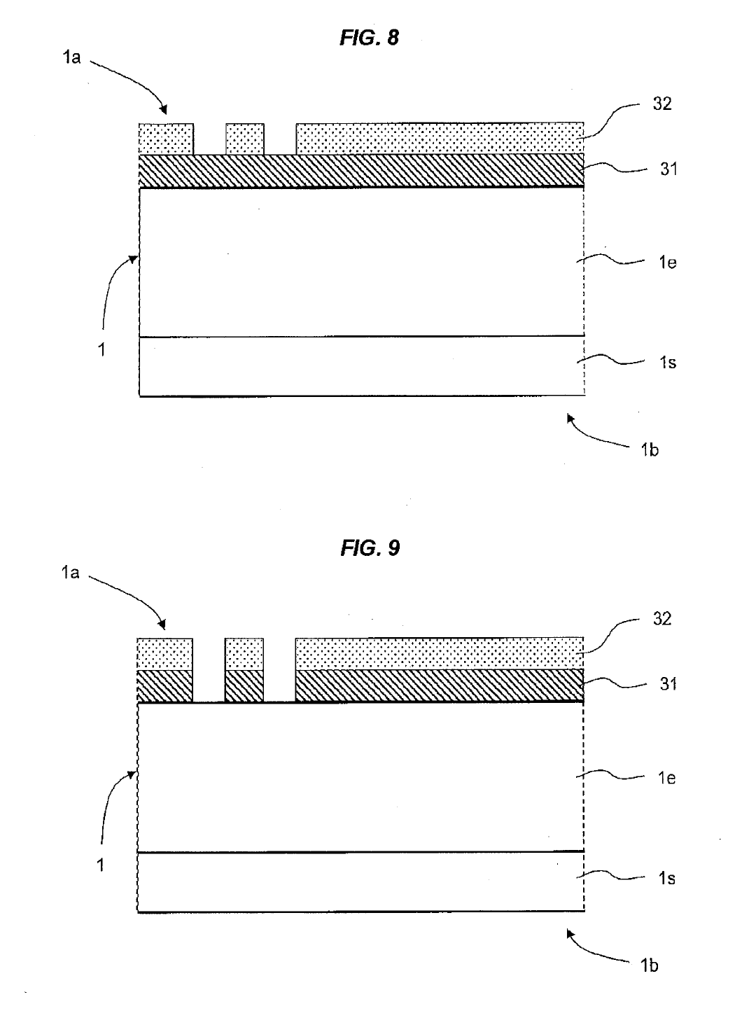

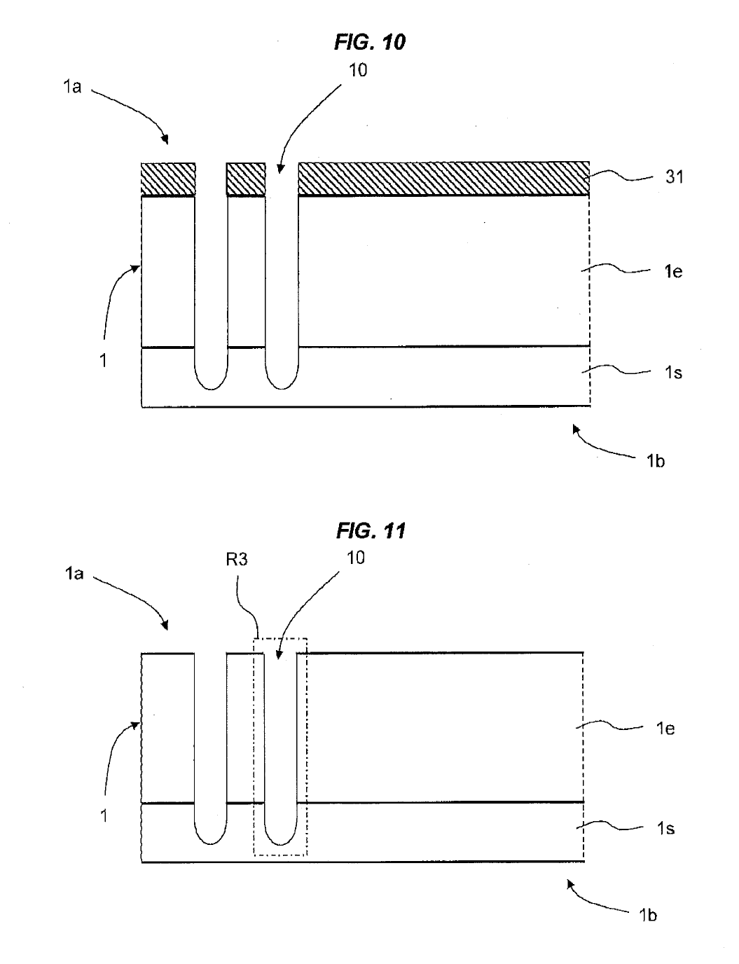

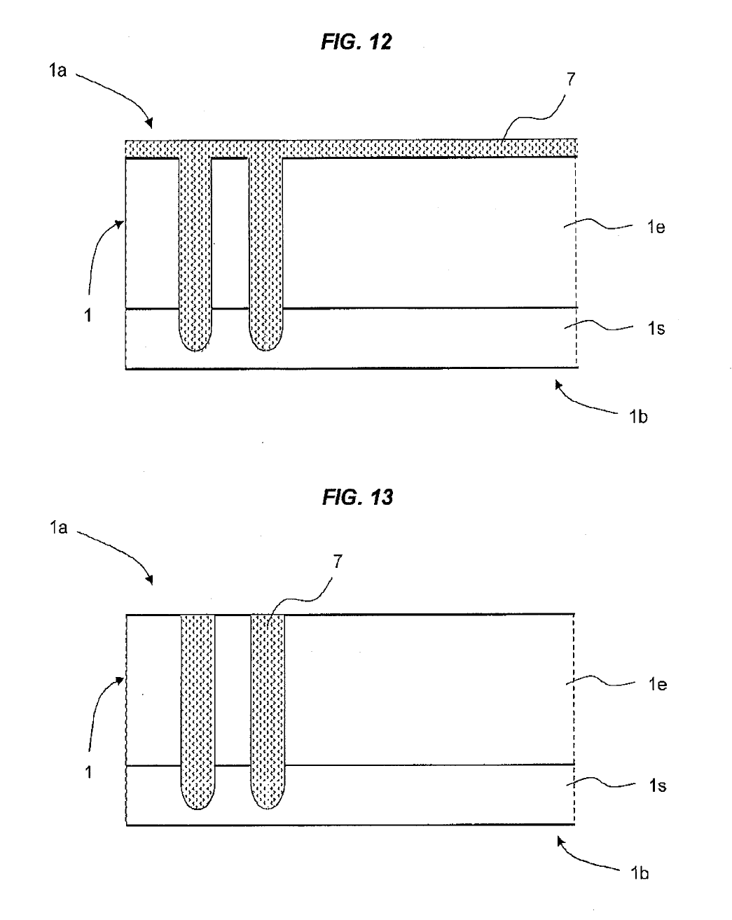

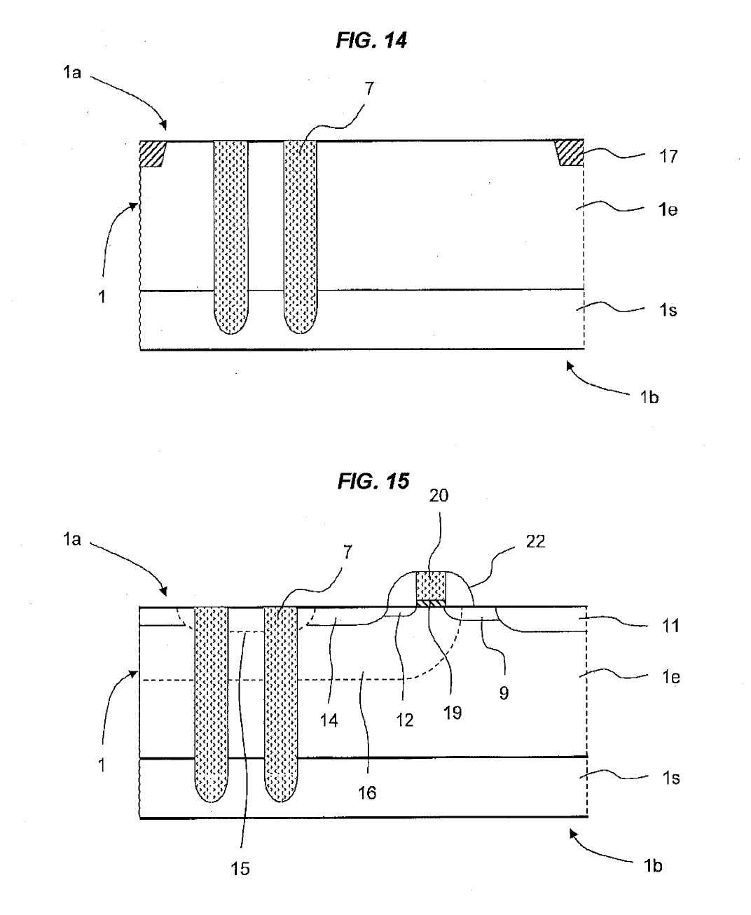

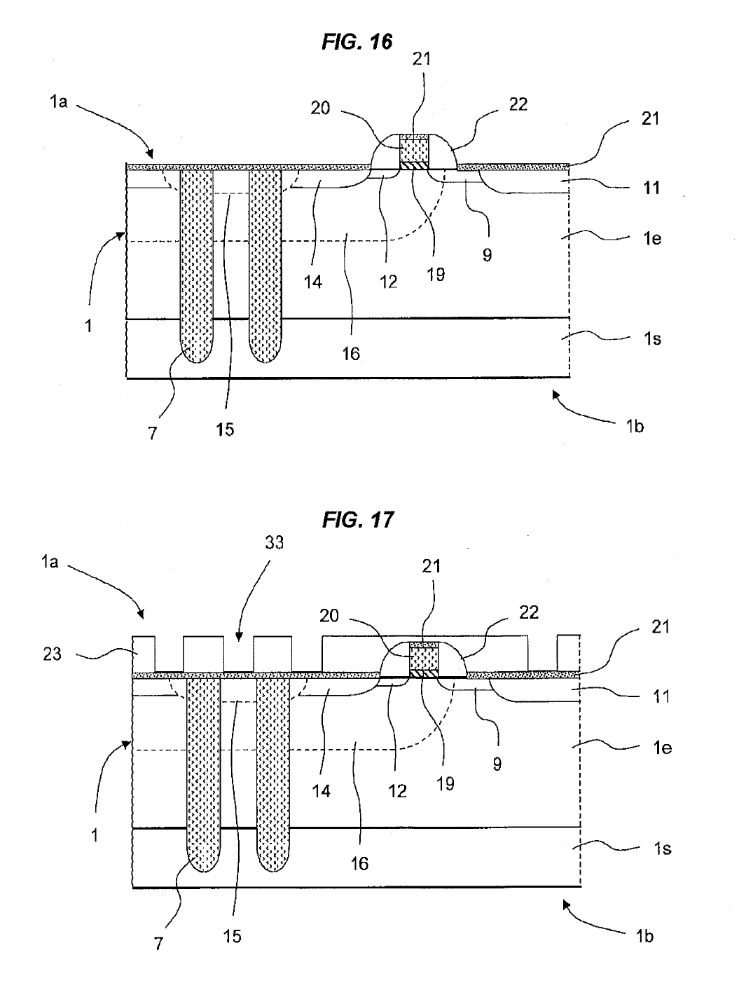

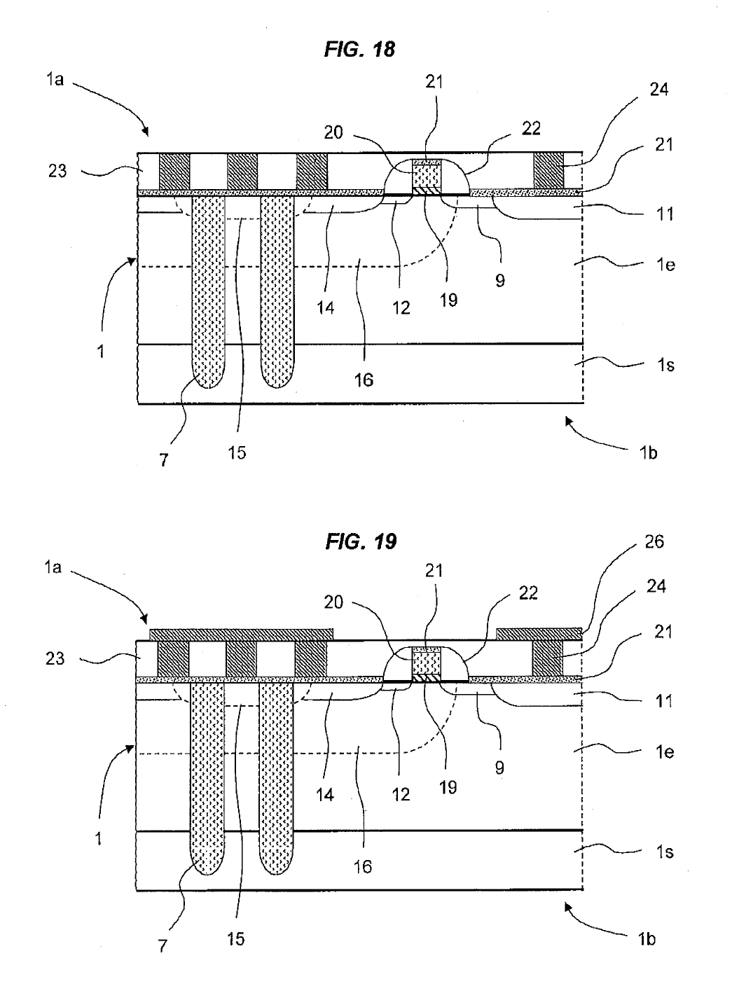

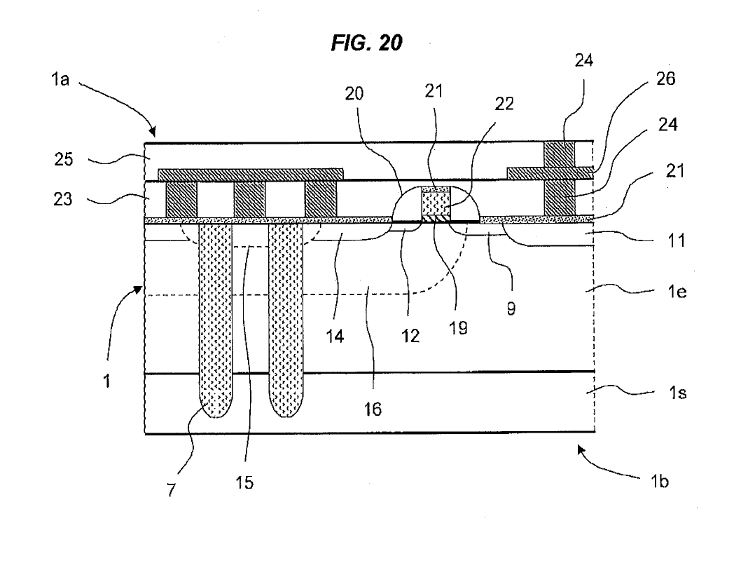

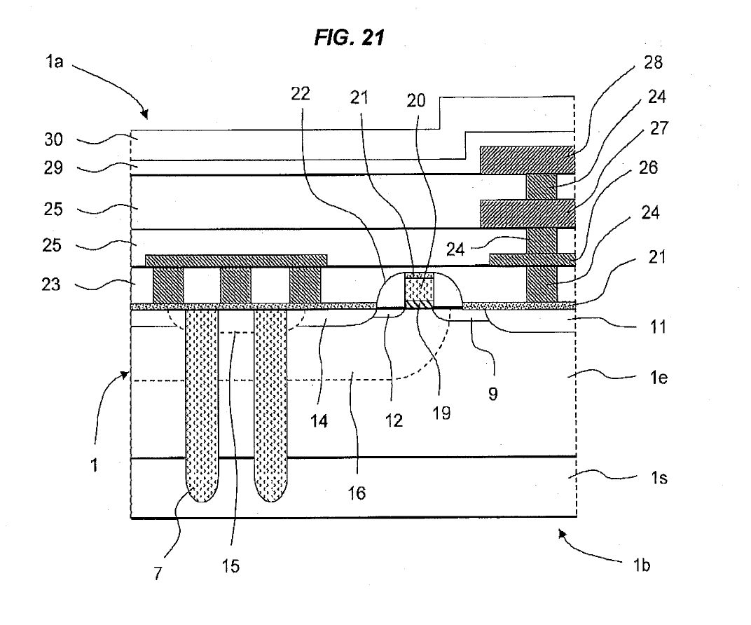

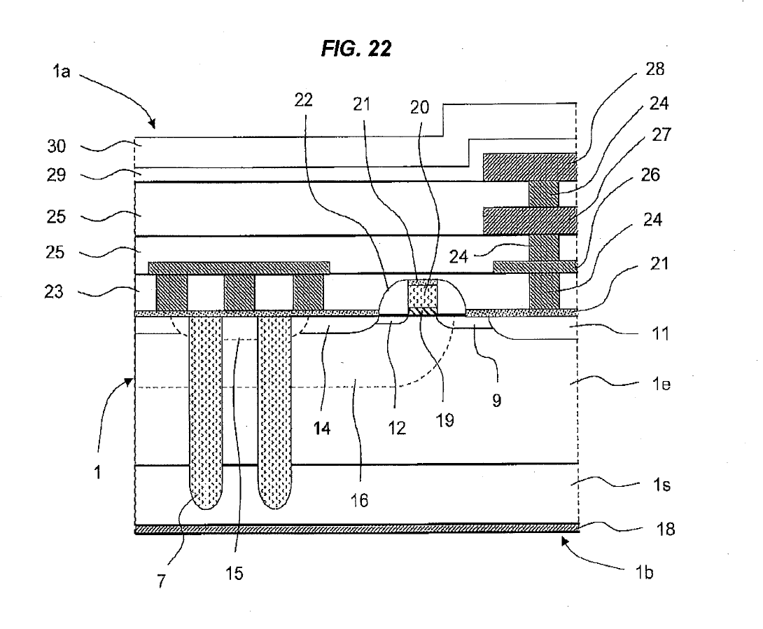

FIG. 6 is a cross-sectional view of a device on the way of a manufacturing step (a step of forming a hard mask film for trench etching) corresponding to FIG. 4 (the cross section indicated by X-X′ in FIG. 3) for outlining the step in the manufacturing method of a semiconductor device in accordance with the embodiment of the present application. FIG. 7 is a cross-sectional view of the device on the way of a manufacturing step (a step of coating a resist film for trench etching) corresponding to FIG. 4 (the cross section indicated by X-X′ in FIG. 3) for outlining the step in the manufacturing method of a semiconductor device in accordance with the embodiment of the present application. FIG. 8 is a cross-sectional view of the device on the way of a manufacturing step (a step of patterning a resist film for trench etching) corresponding to FIG. 4 (the cross section indicated by X-X′ in FIG. 3) for outlining the step in the manufacturing method of a semiconductor device in accordance with the embodiment of the present application. FIG. 9 is a cross-sectional view of the device on the way of a manufacturing step (a step of patterning a hard mask film for trench etching) corresponding to FIG. 4 (the cross section indicated by X-X′ in FIG. 3) for outlining the step in the manufacturing method of a semiconductor device in accordance with the embodiment of the present application. FIG. 10 is a cross-sectional view of the device on the way of a manufacturing step (a step of trench etching) corresponding to FIG. 4 (the cross section indicated by X-X′ in FIG. 3) for outlining the step in the manufacturing method of a semiconductor device in accordance with the embodiment of the present application. FIG. 11 is a cross-sectional view of the device on the way of a manufacturing step (a step of removing a hard mask film for trench etching and a pretreatment step of embedding polysilicon member) corresponding to FIG. 4 (the cross section indicated by X-X′ in FIG. 3) for outlining the step in the manufacturing method of a semiconductor device in accordance with the embodiment of the present application. FIG. 12 is a cross-sectional view of the device on the way of a manufacturing step (a step of embedding polysilicon member) corresponding to FIG. 4 (the cross section indicated by X-X′ in FIG. 3) for outlining the step in the manufacturing method of a semiconductor device in accordance with the embodiment of the present application. FIG. 13 is a cross-sectional view of the device on the way of a manufacturing step (a step of planarizing a surface) corresponding to FIG. 4 (the cross section indicated by X-X′ in FIG. 3) for outlining the step in the manufacturing method of a semiconductor device in accordance with the embodiment of the present application. FIG. 14 is a cross-sectional view of the device on the way of a manufacturing step (a step of forming STI) corresponding to FIG. 4 (the cross section indicated by Y-Y′ in FIG. 3) for outlining the step in the manufacturing method of a semiconductor device in accordance with the embodiment of the present application. FIG. 15 is a cross-sectional view of the device on the way of a manufacturing step (a step of forming a diffusion structure and a gate one) corresponding to FIG. 4 (the cross section indicated by X-X′ in FIG. 3) for outlining the step in the manufacturing method of a semiconductor device in accordance with the embodiment of the present application. FIG. 16 is a cross-sectional view of the device on the way of a manufacturing step (a step of forming a silicide layer) corresponding to FIG. 4 (the cross section indicated by X-X′ in FIG. 3) for outlining the step in the manufacturing method of a semiconductor device in accordance with the embodiment of the present application. FIG. 17 is a cross-sectional view of the device on the way of a manufacturing step (a step of forming a premetal insulating film and a contact hole) corresponding to FIG. (the cross section indicated by X-X′ in FIG. 3) for outlining the step in the manufacturing method of a semiconductor device in accordance with the embodiment of the present application. FIG. 18 is a cross-sectional view of the device on the way of a manufacturing step (a step of embedding a tungsten plug into a contact hole) corresponding to FIG. 4 (the cross section indicated by X-X′ in FIG. 3) for outlining the step in the manufacturing method of a semiconductor device in accordance with the embodiment of the present application. FIG. 19 is a cross-sectional view of the device on the way of a manufacturing step (a step of forming metal first layer tungsten wiring) corresponding to FIG. 4 (the cross section indicated by X-X′ in FIG. 3) for outlining the step in the manufacturing method of a semiconductor device in accordance with the embodiment of the present application. FIG. 20 is a cross-sectional view of the device on the way of a manufacturing step (a step of forming an inter-wiring-layer insulating film and embedding a tungsten plug into a through hole) corresponding to FIG. 4 (the X-X′ cross-section in FIG. 3) for outlining the step in the manufacturing method of a semiconductor device in accordance with the embodiment of the present application. FIG. 21 is a cross-sectional view of the device on the way of a manufacturing step (a step of forming an aluminum-based wiring layer and final passivation) corresponding to FIG. (the cross section indicated by X-X′ in FIG. 3) for outlining the step in the manufacturing method of a semiconductor device in accordance with the embodiment of the present application. FIG. 22 is a cross-sectional view of the device on the way of a manufacturing step (a step of forming a backside metal electrode) corresponding to FIG. 4 (the cross section indicated by X-X′ in FIG. 3) for outlining the step in the manufacturing method of a semiconductor device in accordance with the embodiment of the present application. In accordance with these, the outline of a manufacturing step regarding the LDMOSFET portion in the high-frequency high power amplifier, which is an objective device in the manufacturing method of a semiconductor device of the embodiment of the present application, is explained.

First, a P-type silicon single crystal wafer with a diameter of 200φ (with resistivity of around 2 mΩcm) is prepared (the diameter may be 300φ), 450φ), 150φ), or another size). Subsequently, the P-silicon epitaxial layer 1e with a length of around 2 micrometers (with resistivity of around 20 Ωcm) is grown on the surface 1a of the P-type silicon single crystal wafer 1 (1s).

Next, as shown in FIG. 6, CVD (Chemical Vapor Deposition) forms a hard mask film 31 for forming a trench (for example, a TEOS silicon oxide film having a thickness of around 250 nm) on approximately the whole surface 1a of the wafer 1.

Next, as shown in FIG. 7, a resist film 32 for forming a trench is coated over the hard mask film 31 for forming one.

Next, as shown in FIG. 8, an ordinary lithography patterns the resist film 32 for forming a trench.

Next, as shown in FIG. 9, anisotropic dry etching etches the hard mask film 31 for forming a trench by using the patterned resist film 32 for forming a trench as a mask. Favorable examples of the etching conditions are as follows: Gas flow rates of CHF₃, CF₄, and Ar are 30 sccm, 100 sccm, and 1000 sccm, respectively, treatment ambient pressure is around 200 pascals, RF power is around 1 kilowatt, wafer temperature is around 0° C., treatment time is around 50 seconds. After that, ashing removes the resist film 32 for forming a trench, which has become unnecessary.

Next, as shown in FIG. 10, anisotropic dry etching forms a hole 10 for embedding a plug (a trench for embedding a plug) by using the patterned hard mask film 31 for forming a trench as a mask. Favorable examples of the etching conditions are as follows: Gas flow rates of SF₆ and O₂ are 50 sccm and 20 sccm, respectively, treatment ambient pressure is around 2 pascals, RF power is around 30 watts (microwave power is around 600 watts), wafer temperature is around 50° C., treatment time is around 50 seconds. After that, wet etching removes the hard mask film 31 for forming a trench, which has become unnecessary, by using a chemical solution such as a hydrofluoric acid-based etching solution for a silicon oxide-based film. Then, the state becomes one in FIG. 11.

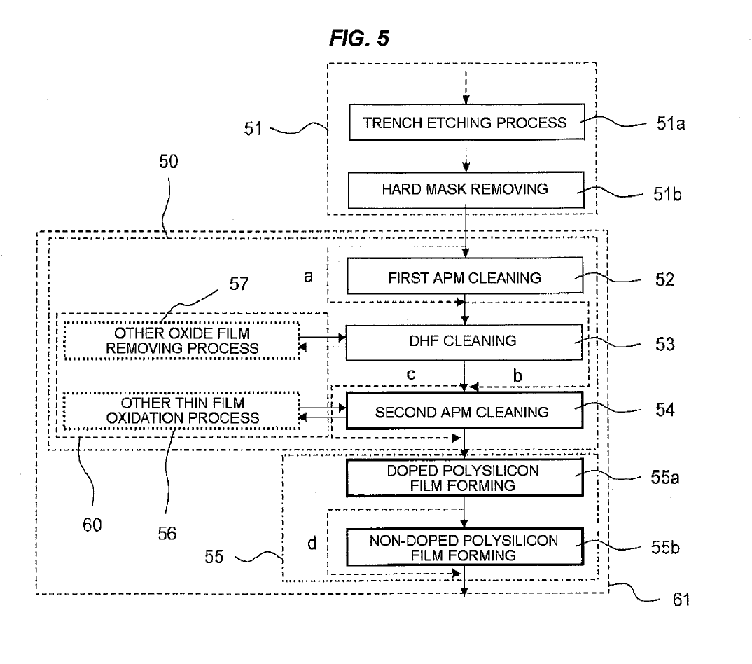

Next, as shown in FIG. 11 (refer to FIG. 5), a pretreatment for embedding polysilicon member (which is described in detail in section 4) is performed on the surface 1a of the wafer 1 and the inner surface of the trench 10 for embedding a plug.

Next, as shown in FIG. 12, CVD embeds the trench 10 for embedding a plug into the approximately whole surface 1a of the wafer 1 by depositing a boron-doped polysilicon member 7 (an embedding polysilicon film forming step 55 in FIG. 5)

Next, as shown in FIG. 13, planarizing the surface 1a of the wafer 1 removes the polysilicon member 7 outside the trench 10 for embedding a plug. The planarization can be performed as an etch back process by dry etching. Favorable examples of the etching conditions are as follows: A gas flow rate of SF₆ is 20 sccm, treatment ambient pressure is around 0.5 pascals, RF power is around 30 watts (microwave power is around 400 watts), wafer temperature is around 20° C., treatment time is around 90 seconds. This finishes the embedding of the polysilicon plug 7.

Next, as shown in FIG. 14 (only in this drawing, the cross-section is changed so that the STI part can be seen), in the same manner as an ordinary STI (Shallow Trench Isolation) process, anisotropic dry etching of the substrate, embedding of a silicon oxide film, and CMP (Chemical Mechanical Polishing) forms an STI region 17 (element isolation region).

Next, as shown in FIG. 15, thermal oxidation (for example, around 800° C. to 1000° C.) forms a gate oxide film 19 on approximately the whole surface 1a of the wafer 1. Subsequently, CVD forms a polysilicon film 20 for a gate electrode on approximately the whole gate oxide film 19, a polysilicon film 20. Subsequently, an ordinary lithography patterns the polysilicon film 20 for a gate electrode. Ion implantation forms the N-type surface source extension region 12 and the N-type drain extension region 9 by using the patterned polysilicon gate electrode 20 as a mask. Subsequently, the sidewall 22 is finished by forming an insulating film 22 for a sidewall such as a silicon oxide film for approximately the whole surface 1a of the wafer 1 and etching back this surface by anisotropic dry etching. Subsequently, regarding the edge of the left sidewall 22, doping an impurity in a self-alignment technique by ion implantation (after the implantation, such heat treatment as activating annealing is performed) forms the P-type body region 16 and the N+-type surface source region 14. Regarding the edge of the right sidewall 22, the N+-type drain region 11 is formed by doping an impurity in a self-alignment technique by ion implantation (after the implantation, such heat treatment as activating annealing is performed). Furthermore, the P+-type surface source contact region 15 is formed around the polysilicon plug 7 by doping an impurity in a self-alignment technique by ion implantation (after the implantation, such heat treatment as activating annealing is performed).

Next, as shown in FIG. 16, a silicide process forms the cobalt silicide film 21 over the surface of the source/drain region and the polysilicon gate electrode 20.

Next, as shown in FIG. 17, CVD forms the premetal insulating film 23 on approximately the whole surface 1a of the wafer 1. Subsequently, an ordinary lithography and anisotropic dry etching open a contact hole 33 is opened.

Next, as shown in FIG. 18, sputtering forms a comparatively thin barrier metal film including a titanium film and a titanium nitride film on approximately the whole surface 1a of the wafer 1 and in the contact hole 33. Subsequently, CVD opens the contact hole 33 in a tungsten film. Subsequently, CMP removes the barrier metal film and the tungsten film outside the contact hole 33 to form the tungsten plug 24.

Next, as shown in FIG. 19, sputtering forms a tungsten film on approximately the whole surface 1a of the wafer 1 and an ordinary lithography patterns this film to form the tungsten-based first layer wiring 26.

Next, as shown in FIG. 20, plasma CVD forms the interlayer insulating film 25 over the premetal insulating film 23 and the tungsten-based first layer wiring 26. Subsequently, an ordinary lithography and anisotropic dry etching open a through hole (a via hole) in the interlayer insulating film 25. Then, in the mentioned manner, the tungsten plug 24 is embedded and formed in the through hole.

Next, as shown in FIG. 21, sputtering forms the aluminum-based wiring layer 27 on approximately the whole upper surface of the interlayer insulating film 25 over the tungsten-based first layer wiring 26. Subsequently, an ordinary lithography patterns the aluminum-based wiring layer 27 (the aluminum-based second layer wiring). Furthermore, in the mentioned manner, an uppermost layer wiring layer is formed by repeating the deposition of the interlayer insulating film 25, the film forming of the aluminum-based third layer wiring 28 and patterning. Subsequently, plasma CVD forms the silicon oxide-based final passivation film 29 and the silicon nitride-based final passivation film 30 over the uppermost layer wiring layer

Next, as shown in FIG. 22, as necessary, after back grinding sets the thickness of the wafer 1 to an intended thickness, sputtering forms the backside metal source electrode 18 on approximately the whole backside lb of the wafer 1. After that, as necessary, dicing singulates the wafer 1 into the individual chip region 2.

4. Explanation of detailed steps of the essential part of a manufacturing step regarding the LDMOSFET portion in the high-frequency high power amplifier, which is an objective device in the manufacturing method of a semiconductor device in accordance with an embodiment of the present application (mainly FIG. 5 and FIGS. 24 to 26). This section explains details of processes from FIGS. 10 to 12 in the section 3 (a pretreatment step group for embedding a polysilicon member).

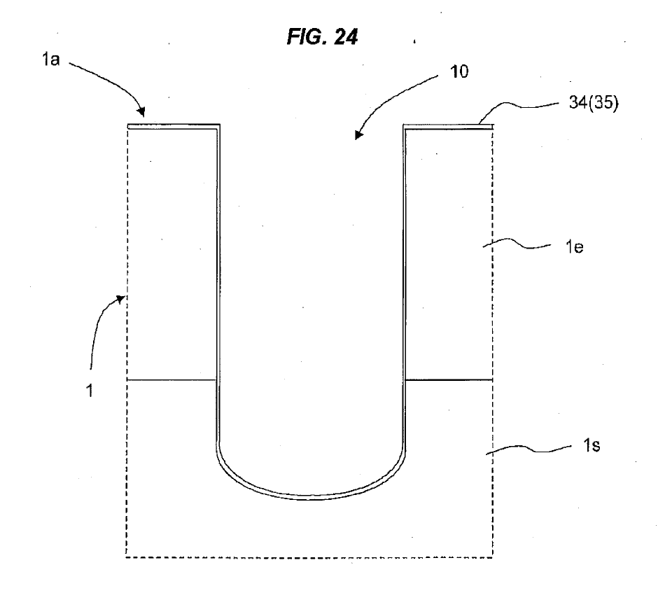

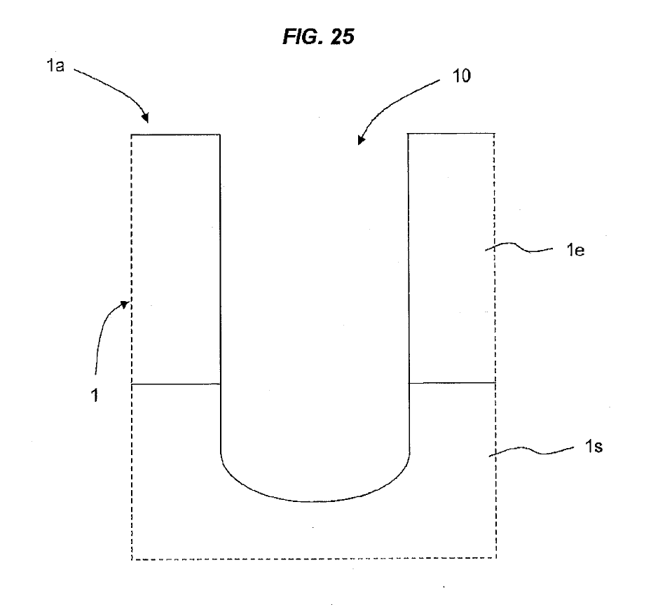

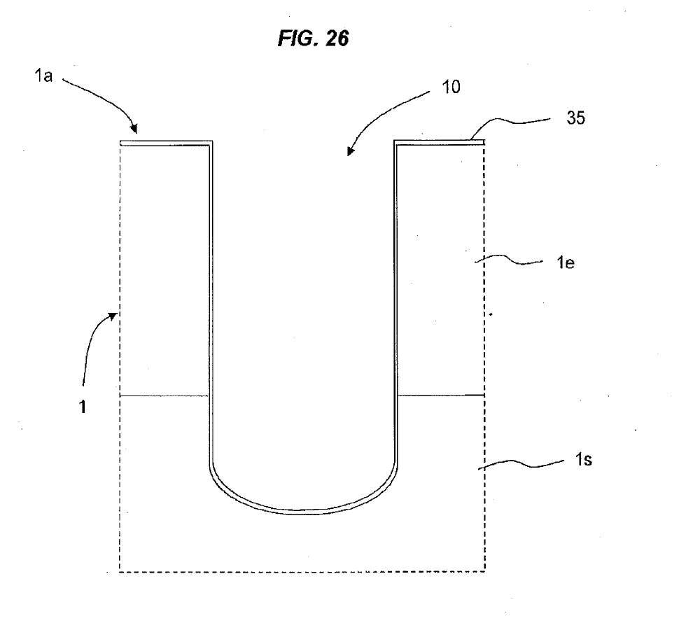

FIG. 5 is a flowchart of a pretreatment step of embedding polysilicon member, which is the essential part in the manufacturing method of a semiconductor device in accordance with the embodiment of the present application. FIG. 24 is an expanded schematic cross-sectional view (for purposes of illustration, the horizontal width and thicknesses of a natural oxide film 34 and a thin silicon oxide film 35 are exaggerated, but they are original in FIGS. 25 and 26) of the region 3 cut out from the region near the polysilicon plug for explaining the detailed step (before a pretreatment step of embedding the polysilicon member or on completion of the first APM cleaning) of the step in FIG. 11. FIG. 25 is an expanded schematic cross-sectional view of the region R3 cut out from the region near the polysilicon plug for explaining the detailed step (on completion of the DHF cleaning) of the step in FIG. 11. FIG. 26 is an expanded schematic cross-sectional view of the region R3 cut out from the region near the polysilicon plug for explaining the detailed step (on completion of the second APM cleaning) of the step in FIG. 11. In accordance with these, the detailed steps of the essential part of a manufacturing step regarding the LDMOSFET portion in the high-frequency high power amplifier, which is an objective device in the manufacturing method of a semiconductor device in accordance with the embodiment of the present application, are explained.

(1) Treatment Based on Standard Cleaning Process

As shown in FIG. 5, after the end of a removing step 51b of a hard mask film 31 for forming a trench (a trench etching post-treatment) after a trench etching process 51a of a trench etching step 51, for the treatment of steps belonging to a subsequent embedding polysilicon film forming step group 61, a step belonging to a pretreatment step group 50 for embedding a polysilicon member is first preformed on the wafer 1.

First, as shown in FIG. 5, a first APM cleaning step 52 (a cleaning step by a third chemical solution) is performed. This is a wet cleaning process (a wet surface treatment) performed by using an APM (Ammonia/Hydrogen Peroxide Mixture) as a chemical solution. Favorable examples of the conditions are as follows: a volume composition ratio of ammonia, hydrogen peroxide solution, and water is 0.2:1:10 (an aqueous solution including ammonia or a hydrogen peroxide solution as one of main components, which has such property as forming an oxide film on a silicon surface), liquid temperature is around 50° C., and treatment time is around 10 minutes.

As shown in FIG. 24, the thin silicon oxide film 35 (a thin silicon oxide-based film or a thin silicon oxide film) is formed on the surface of the wafer 1 (including the inner surface of the trench 10) at the stage (the completion of the first APM cleaning step 52. The state is approximately the same as the one before this step). This is an integrated film of a natural oxide film and a chemical oxide film which is formed in the first APM cleaning step 52. Generally, in a wet surface treatment by a chemical solution including a hydrogen peroxide solution being an oxidizing agent as a main component and including no silicon oxide film etching agents such as hydrofluoric acid, like APM, a chemical oxide film is formed on the surface of a silicon-based semiconductor such as silicon. The natural oxide film 34 and the chemical oxide film have a thickness of about 0.2 nm to about 2 nm. They can be cited as a thin silicon oxide film 35. The wafer 1 on which the first APM cleaning step 52 has finished is usually sent to the next step via a water washing step.

Next, as shown in FIG. 5, a DHF cleaning step 53 for removing an oxide film of the surface (a cleaning step by the first chemical solution or a first surface treatment step) is performed on the wafer 1 that the water washing has finished after the first APM cleaning step 52. This is a wet cleaning process (wet surface process) performed by using DHF (Diluted Hydrogen Fluoride) as a chemical solution. Favorable examples of the conditions are as follows: A volume composition ratio of HF and water is 1:500 (an aqueous solution containing hydrofluoric acid as one of main components, which has a property of removing an oxide film of the silicon surface), liquid temperature is around 25° C., and treatment time is around 15 minutes. FIG. 25 shows the cross section of the wafer 1 on the completion of the DHF cleaning step 53. The thin silicon oxide film 35 has been removed approximately completely. The wafer 1 on which the DHF cleaning step 53 has finished is usually sent to the next step via a water washing step.

Next, as shown in FIG. 5, the second APM wet treatment step 54 for forming an oxide film (a wet treatment step or a second surface treatment step by a second chemical solution) is performed on the wafer 1 that the water washing has finished after the DHF cleaning step 53, This is a wet cleaning process (wet surface treatment) performed by using the APM as a chemical solution (oxidizing chemical solution). Favorable examples of the conditions are as follows: A volume composition ratio of ammonia, hydrogen peroxide solution, and water is 0.2:1:10 (an aqueous solution containing ammonia or a hydrogen peroxide solution as one of main components, which has such property as forming an oxide film on a silicon surface), liquid temperature is around 50° C., treatment time is around 10 minutes.

As shown in FIG. 26, the thin silicon oxide film 35 (a thin silicon oxide-based film or a thin silicon oxide film) is formed on the surface of the wafer 1 (including the inner surface of the trench 10) at this stage (the completion of the second APM wet treatment step 54). This is a chemical oxide film formed in the second APM cleaning step 54. Generally, in a wet surface treatment by a chemical solution including a hydrogen peroxide solution being an oxidizing agent as a main component and including no silicon oxide film etching agents such as hydrofluoric acid, like APM, a chemical oxide film is formed on the surface of a silicon-based semiconductor such as silicon. The chemical oxide film has a thickness of around 0.2 nm to around 2 nm. It can be cited as a thin silicon oxide film 35. The wafer 1 on which the second APM cleaning step 54 has finished is usually sent to the next step via a water washing step and a drying step.

As shown in FIG. 5, a treatment belonging to the subsequent embedding polysilicon film forming step 55 is performed on the wafer 1 on which water washing and drying have finished after the second APM cleaning step 54. The embedding polysilicon film forming step 55 is favorably performed out before a natural oxide film is formed again. Even if a natural oxide film is formed again, no problem occurs when it is in a range of a thin oxide film.

The embedding polysilicon film forming step 55 is usually performed as follows. First, on approximately the whole surface 1a of the wafer 1 (including the inside and the inner surface of the trench 10), a boron-doped polysilicon film having a thickness of around 400 nm (the dose quantity is around 7×10²⁰/cm³) is deposited by CVD (the film forming temperature is around 400° C.) to make the inside of the trench 10 be an approximately filled state (a doped polysilicon film forming step 55a in FIG. 5). Subsequently, on approximately the whole surface 1a of the wafer 1, a non-doped polysilicon film having a thickness of around 100 nm (this layer is usually removed by the planarization later) is deposited by CVD (the film forming temperature is around 530° C.) (a non-doped polysilicon film forming step 55b in FIG. 5). The wafer 1 on which the embedding polysilicon film forming step 55 has finished is in a state in FIG. 12. The non-doped polysilicon film is effective in preventing outward diffusion of boron. But, if there is no such anxiety, the step can be skipped (a bypass process 4(d)). In this case, the boron-doped polysilicon film may be thickened.

(2) Various Modified Examples

Since the embodiment explained is an embodiment in which the embedding polysilicon film is deposited in a state where a thin oxide film exists. The DHF cleaning step 53 is not limited to the step explained before, but any may be suitable if it is a step of removing the whole natural oxide film. In addition to DHF cleaning (as a wet etching, one using another chemical solution including hydrofluoric acid is also possible), another oxide film removing treatment step 57 (a second surface treatment step) such as an isotropic dry etching is considered.

The second APM wet treatment step 54 (FIG. 5) is not limited to the step explained before, but any may be suitable if it is a method capable of forming a thin silicon oxide-based film 35 (a thin silicon oxide film). As the other thin film oxidation treatment step 56 (a first surface treatment step), the following is considered: A wet treatment by another oxidizing chemical solution such as an SPM (Sulfuric Acid/Hydrogen Peroxide Mixture) or ozone water, thermal oxidation in a diluted atmosphere (an oxygen atmosphere diluted with a large quantity of nitrogen), CVD such as ALD (Atomic Layer Deposition), sputtering film forming, a plasma oxidation process, and a natural oxidation process (leaving as it is to generate a natural oxide film). To use the natural oxide film 34 (FIG. 24) directly as the thin silicon oxide-based film 35, the DHF cleaning step 53 (a cleaning process by the first chemical solution or the first surface treatment process) and the second APM wet treatment process 54 (a wet treatment process by the second chemical solution or the second surface treatment process) can be skipped (a bypass process 2(b) and a bypass process 3(c)).

When a chemical oxidation process by an SPM are compared with the second APM wet treatment process 54, the second APM wet treatment process 54 can perform the process using a comparatively low temperature chemical solution.

Moreover, the first APM cleaning process 52 is effective in removing the pollution of the surface of the wafer 1, but is not indispensable (a bypass process 1(a)).

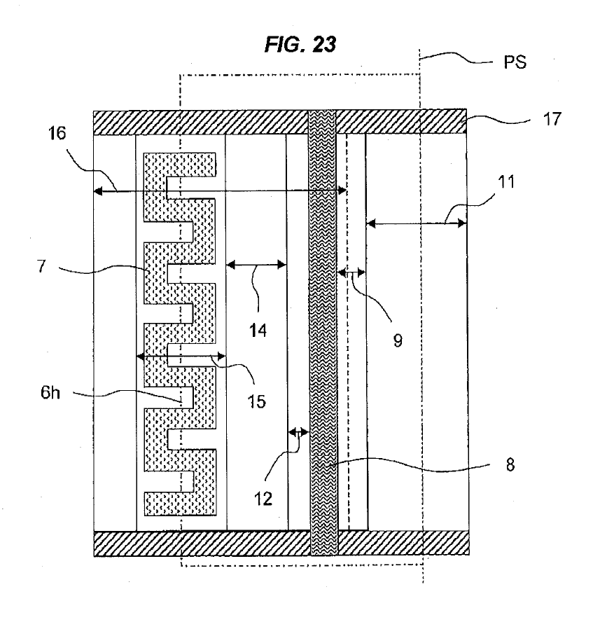

5. Explanation of a modified example of the device structure (mainly FIG. 23). In this section, a modified planar layout of the polysilicon plug 7 in FIG. 3 is explained.

FIG. 23 is an expanded plan view corresponding to the region R2 cut out from the region near the half cell in FIG. 2 for explaining a modified device structure corresponding to FIG. 3. In accordance with this, a modified device structure is explained.

As shown in FIG. 23, two polysilicon plugs 7 in FIG. 3 are set to be one polysilicon plug 7 that is zigzag in a plane in the example. This zigzag is selected to gain an area efficiency.

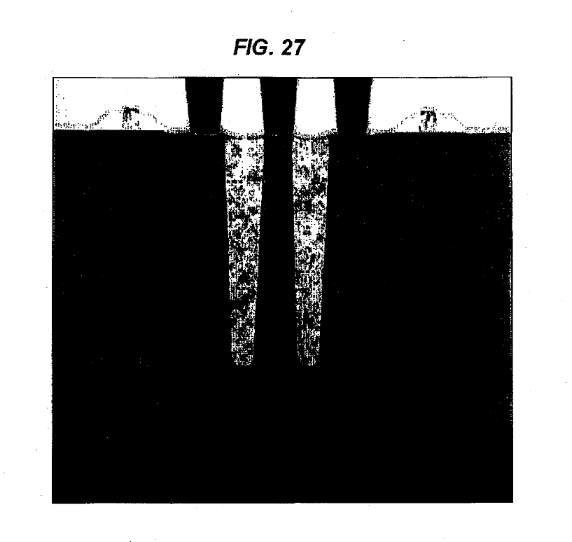

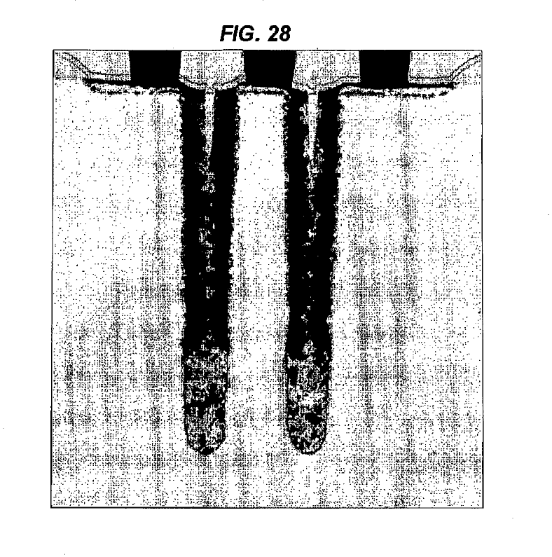

6. Consideration and a complementary explanation regarding the embodiments (including modified examples) (mainly FIGS. 27 and 28). FIG. 27 is a cross-sectional SEM (Scanning Electron Micrograph) which shows the region near the silicon plug of the semiconductor device in the manufacturing method of a semiconductor device in accordance with the embodiment of the present application. FIG. 28 is a cross-sectional SEM (Scanning Electron Micrograph) of the region near the silicon plug of a semiconductor device by a cleaning step in comparative example (corresponding to the bypass process 3(c)) (a cleaning step without the second APM cleaning in FIG. 5). In accordance with these, a complementary explanation and consideration regarding the embodiments (including modified examples) are performed.

FIG. 28 corresponds to comparative example. Only the second APM wet treatment step 54 is skipped as the bypass process 3(c), although other conditions are the same as those for the above-mentioned embodiment. Polysilicon is embedded in a state that no oxide film exists on the silicon surface in the trench 10. A black part of the polysilicon plug part in FIG. 28 shows that solid phase epitaxy grows. In contrast, according to FIG. 27, almost no solid phase epitaxy grows on the sample into which the embedding polysilicon is embedded, as the embodiment, in the state where the thin silicon oxide-based film 35 (a thin silicon oxide film) exists. The reason for this is considered that the thin oxide film prevents the growth of solid epitaxy of the polysilicon plug part, which occurs along with a high temperature heat treatment (heat treatments performed at 800° C. or more such as an STI formation process, gate oxidation and an activating annealing after ion implantation).

7. Summary

The invention made by the present inventor is explained specifically in accordance with the embodiment. The present invention is not limited to it, but may be changed variously in a range that does not deviate from the purport.

In the embodiment, the case where the LDMOSFET is the LDMOSFET portion or the LDMOSFET forming portion of the semiconductor integrated circuit device is explained specifically. But the invention is not limited to it and the LDMOSFET may be formed as an individual device.

What is claimed is:

1. A manufacturing method of a semiconductor device, comprising the steps of:
(a) preparing a first conductivity type silicon-based single crystal wafer having a first semiconductor layer of a first impurity concentration, and a second semiconductor layer of a second impurity concentration contacting the boundary with the first semiconductor layer and having the same conductivity type as the first semiconductor layer;
(b) forming a plug-embedding hole that passes through the second semiconductor layer from a first main surface of the wafer toward a second main surface on the first semiconductor layer to reach an inside of the first semiconductor layer;
(c) after the step (b), depositing a polysilicon member on the first main surface of the wafer in a state where a thin silicon oxide-based film exists on the inner surface of the hole to embed the inside of the hole with the polysilicon member;
(d) removing the polysilicon member outside the hole to form a polysilicon plug; and
(e) after the step (d), performing a heat treatment on the wafer at 800° C. or more.

2. The manufacturing method of a semiconductor device according to claim 1,
wherein the polysilicon plug constitutes a current path between a surface source region being an LDMOSFET, or an LDMOSFET portion of the semiconductor device and provided on the first principal face side of the wafer, and a back-face source electrode provided on the second principal face side of the wafer.

3. The manufacturing method of a semiconductor device according to claim 1,
wherein the polysilicon plug constitutes a current path between a surface source region being an LDMOSFET portion of the semiconductor device and provided on the first main surface of the wafer, and a backside source electrode provided on the second main surface of the wafer.

4. The manufacturing method of a semiconductor device according to claim 3,
wherein the polysilicon plug is doped with boron.

5. The manufacturing method of a semiconductor device according to claim 4,
wherein the first semiconductor layer is a P-type silicon substrate of the wafer, and the second semiconductor layer is a P-type epitaxial silicon layer of the wafer.

6. The manufacturing method of a semiconductor device according to claim 5,
wherein CVD deposits the polysilicon member.

7. The manufacturing method of a semiconductor device according to claim 6,
wherein an oxidizing chemical solution forms the thin silicon oxide-based film.

8. The manufacturing method of a semiconductor device according to claim 7, further comprising the step of
(f) after the step (b) and before the step(c),performing a pretreatment for embedding a polysilicon member
wherein the step (f) includes the substeps of:
(f1) performing a cleaning process on the surface on the first main surface of the wafer including the inner surface of the plug-embedding hole by a first chemical solution that has a function of removing an oxide film; and
(f2) after the substep (f1), performing a wet process on the surface on the first main surface of the wafer including the inner surface of the plug-embedding hole by a second chemical solution that has a function of forming an oxide film.

9. The manufacturing method of a semiconductor device according to claim 8,
wherein the second chemical solution is an aqueous solution including a hydrogen peroxide solution as one of main components.

10. The manufacturing method of a semiconductor device according to claim 9,
wherein the second chemical solution is an aqueous solution including ammonia as one of main components.

11. The manufacturing method of a semiconductor device according to claim 10,
wherein the first chemical solution is an aqueous solution including hydrofluoric acid as one of main components.

12. The manufacturing method of a semiconductor device according to claim 11,
wherein the step (f) further includes the substep of
(f3) before the substep (f1), performing a cleaning process on the surface on the first main surface of the wafer including the inner surface of the plug-embedding hole by a third chemical solution that has a function of forming an oxide film.

13. The manufacturing method of a semiconductor device according to claim 12,
wherein the third chemical solution is an aqueous solution including a hydrogen peroxide solution as one of main components.

14. The manufacturing method of a semiconductor device according to claim 13,
wherein the third chemical solution is an aqueous solution including ammonia as one of main components.

15. The manufacturing method of a semiconductor device according to claim 11,
wherein the thickness of the thin silicon oxide-based film at the start of the step (c) is from about 0.2 nm to about 2 nm.

16. The manufacturing method of a semiconductor device according to claim 6,
wherein the thin silicon oxide-based film is a natural oxide film.

17. The manufacturing method of a semiconductor device according to claim 6,
wherein the thin silicon oxide-based film is a thermal oxide film.

18. The manufacturing method of a semiconductor device according to claim 6,
wherein the thin silicon oxide-based film is an oxide film formed by CVD.

19. The manufacturing method of a semiconductor device according to claim 6,
wherein the thin silicon oxide-based film is an oxide film formed by plasma oxidation.

20. The manufacturing method of a semiconductor device according to claim 6, further comprising the step of
(f) after the step (b) and before the step (c), performing a pretreatment for embedding a polysilicon member,
wherein the step (f) includes the substeps of:
(f4) performing a first surface treatment that has a function of removing an oxide film from the surface on the first main surface of the wafer including an inner surface of the plug-embedding hole; and
(f5) after the substep (f4), performing a second surface treatment that has a function of forming an oxide film on the surface on the first main surface of the wafer including the inner surface of the plug-embedding hole.
